(19) United States
(12) Patent Application Publication
(10) Pub. No.: US 2013/0169302 A1
(43) Pub. Date: Jul. 4, 2013

(54) SYSTEM AND ADAPTER FOR TESTING PACKAGED INTEGRATED CIRCUIT CHIPS

(71) Applicant: STMicroelectronics S.r.I., Agrate Brianza (MB) (IT)

(72) Inventor: Raffaele Ricci, Milano (IT)

(73) Assignee: STMICROELECTRONICS S.R.L., Agrate Brianza (MB) (IT)

(21) Appl. No.: 13/714,553

(22) Filed: Dec. 14, 2012

(30) Foreign Application Priority Data
Dec. 30, 2011 (IT) VI2011A000343

(51) Int. Cl. G01R 31/28

(52) U.S. Cl. CPC G01R 31/2887
USPC 324/750.25; 324/756.05

(57) ABSTRACT

High precision connectivity for a device under test (DUT) in an electronic test system at reduced cost and superior performance characteristics is provided by incorporating an appropriate contact structure into a printed circuit board (PCB) of the electronic test system. Alternatively, a superior adapter that is formed on the basis of highly precise volume production techniques, for example using well-established semiconductor materials and related manufacturing techniques, is provided to support high precision connectivity.

### PRIORITY CLAIM

This application claims priority from Italian Application for Patent No. VI2011A000343 filed Dec. 30, 2011, the disclosure of which is incorporated by reference.

### TECHNICAL FIELD

Generally, the present invention relates to the field of testing packaged integrated circuit chips, for instance in the form of burn-in tests prior to assembling an electronic device or system that comprises the packaged integrated circuit chips.

### BACKGROUND

Immense progress has been made in the field of semiconductor production techniques by steadily reducing the critical dimensions of circuit elements, such as transistors, in highly complex integrated circuits. For example, critical dimensions of 30 nm and less have been implemented in highly complex logic circuitry and memory devices, thereby achieving high packing density. Consequently, more and more functions may be integrated into a single semiconductor chip, thereby providing the possibility of forming entire systems on chip so that highly complex electronic circuits may be formed on the basis of a common manufacturing process.

Typically, upon increasing the complexity of an integrated circuit provided on a single semiconductor chip also the input/output (I/O) capabilities have to be increased in order to address the demands for communication with peripheral circuitry in complex electronic systems. To this end, one or more semiconductor chips are attached to an appropriate substrate or package, which may impart superior thermal and mechanical integrity to the sensitive semiconductor chips and which may also represent an appropriate interface so as to provide an electrical connection from the integrated circuit to a peripheral electronic component, such as a printed circuit board (PCB), which in turn may have any appropriate configuration so as to represent a part of an overall complex electronic system.

The remarkable advances in the field of semiconductor technology, however, also lead to significant challenges throughout the entire manufacturing flow starting with the providing of the semiconductor-based material and ending with the complex packaged semiconductor device, which is to be implemented into a complex electronic system. Consequently, throughout the entire manufacturing flow a plurality of test and control mechanisms are implemented, in which measurement results are obtained so as to qualify the various processes. In particular, at the end of the wafer-based fabrication of complex semiconductor die, each of which may have included therein one or more integrated circuits, detailed electric tests are performed so as to identify fatal failures in the semiconductor devices and/or determine performance characteristics of functioning devices. To this end, usually appropriate test programs have to be applied, in which, for instance, built in self test (BIST) circuitry may frequently be used in combination with specifically defined test algorithms in order to obtain a high failure coverage, while nevertheless ensuring a time efficient procedure. Typically, the semiconductor die are packaged and subjected to a final electrical test so as to verify performance and reliability of the final semiconductor device prior to implementing the device in a complex electronic system, since typically any premature failure of the semiconductor device in an already assembled complex electronic system would much more contribute to the overall cost of electronic systems than identifying faulty packaged semiconductor devices prior to shipping these devices. Thus, during the final electrical test typically sophisticated operation conditions are established, for instance in terms of increased temperatures and elevated voltages in order to accelerate electrical failure of semiconductor devices having reduced reliability. According to this strategy it is assumed that a fatal failure of the semiconductor device may preferably occur at an early phase of its operational lifetime so that non-reliable semiconductor devices may efficiently be identified on the basis of such final electrical test procedures, which are also referred to as burn in tests.

During such a final electrical test the semiconductor devices are typically installed in an appropriate test environment, which comprises an integrated circuit board (PCB) in order to allow operation of the semiconductor device at sophisticated operating conditions, wherein during the entire test or at least at the end of such a test functionality of the semiconductor device is to be verified. Also in this case appropriate test procedures have to be applied in order to be able to identify any possible failure in any of the circuit components, such as memory areas, complex control logic, and the like.

Upon introducing burn in tests appropriate test sockets have been employed, which are appropriately configured to allow a reliable temporal installation of the semiconductor device in the test environment. One critical aspect in using burn in sockets is the contact to the PCB, which is typically accomplished by using contact elements, which ensure mechanical and electrical connection to the PCB. With respect to the mechanical aspect of the connection the contact element has to provide sufficient compliance and mechanical force in order to mechanically hold in position the device under test (DUT). Furthermore, the mechanical contact has to be maintained for a large number of devices to be tested in order to guarantee similar test conditions for each of the semiconductor devices. Moreover, as discussed above, the mechanical contact has to be preserved at high temperature so as to allow the establishment of sophisticated test conditions. With respect to the electrical aspects of the contact element its resistance should not significantly change over time, while nevertheless the contact element has to be able to provide the maximum current for the DUT. In addition, since the operating frequency of modern semiconductor devices has significantly increased over the last decades, the burn in sockets and in particular the contact elements should not unduly affect the signals in order to allow the desired operating frequency to be applied during the burn in test. In order to address these requirements, the contact elements have been made on the basis of appropriate metal that is stamped into any appropriate shape so as to provide for the required elasticity and current drive capability. For example, sufficient elastic characteristics may be obtained by ensuring a sufficient mechanical beam length of the contact element, while on the other hand the current drive capability is ensured by appropriately dimensioning the cross-sectional area of the contact element.

As already discussed above, due to the increasing complexity of semiconductor devices also the connection counts of the semiconductor packages may significantly increase, which may be in the range of more than 3000 connections, thereby requiring reliable contact to each of the connections without damaging pads or solder balls on the package. However, the reliable contacting of a large number of connections of the semiconductor package may require appropriately designed contact elements in order to decouple the mechanical and electrical aspects of the contact elements, which may result in significant additional costs in providing sophisticated burn in sockets. For example, spring probes typically made from two or three screw machine parts and a coiled spring may be used so as to provide sufficient electrical and mechanical contact without unduly damaging the contact elements on the semiconductor package. The fabrication of the spring probes, however, is highly cost intensive and thus contributes to significant cost of the burn in test procedure. Hence, although modern burn in sockets may allow the application of a single test program for evaluating functionality of the semiconductor device, thereby reducing any effort for optimizing the test programs, and generally installation of the device under test on the PCB may be accomplished substantially without additional installation time, there are several disadvantages associated with the use of even sophisticated burn in sockets. For instance, inductive loads caused by the required length of the contact elements may result in electrical failures of the DUT during the test procedure. Furthermore, the burn in sockets may provide limited heat dissipation capabilities or may limit the applicability of sophisticated temperature conditions during the test procedure. Furthermore, the contact elements of the socket may suffer from surface modifications, such as oxidation, thereby significantly changing the contact resistivity. Additionally, typically the layout in the test environment is not optimized for any external components, such as filter capacitors, and the like using burn in sockets. Furthermore, as discussed above, for sophisticated contact regimes of the semiconductor package, such as ball grid arrays (BGA) with a high number of individual balls the costs for the socket may be very expensive.

For these reasons, alternative solutions have been proposed, in which a dedicated PCB is used for routing the various electrical connections for a complex semiconductor package, which is attached to the dedicated PCB by a solder process. In this manner, superior thermal connection to the environment is achieved, while also good contact formation between the DUT and the PCB contributes to reliable test behavior due to the avoidance of contact oxidation. Furthermore, the conductors may be generally shorter, thereby reducing the inductive load. Similarly, implementing the connection by a dedicated PCB and a solder process may be provided at low cost, even for highly complex contact regimes. On the other hand, the layout is typically not optimized for external components, such as filter capacitors and significant additional time is required for attaching and detaching the semiconductor device to and from the PCB. Moreover, specific test programs may be necessary, thereby requiring additional time and resources for implementing the final electrical test procedures.

In view of this situation it is an object of the present invention to provide a contact regime for installing semiconductor devices, for instance packaged semiconductor devices, in a test environment while avoiding or at least reducing one or more of the problems identified above.

### SUMMARY

Generally, the present invention addresses the above identified problem by providing a contact regime, which combines advantageous features, such as low-cost, compatibility with efficient test procedures, high mechanical and electrical integrity while at the same time ensuring reduced installation time of a semiconductor device to be tested.

According to one aspect an electronic test system comprises a printed circuit board having a first surface and an oppositely arranged second surface. The electronic test system further comprises a support structure attached to the printed circuit board and configured to receive and hold in position a packaged semiconductor device to be tested. Moreover, the electronic test system additionally comprises a contact structure formed on the printed circuit board and configured to directly and removably connect to a complementary contact structure of the packaged semiconductor device to be tested.

According to an embodiment the contact structure is directly integrated into the printed circuit board so as to enable the installation of the DUT directly on the PCB so that short installation times may be achieved. The support structure ensures a reliable electrical contact of the complementary contact structure of the DUT and the board internal contact structure, while at the same time the correct lateral position of the DUT is determined by the support structure. Consequently, efficient test programs may be applied during the production of the DUT and the final burn in test on the basis of the inventive electronic test system, thereby avoiding additional time and resources for optimizing test programs. Similarly to conventional sophisticated burn in sockets the installation of the DUT in the electronic test system may be accomplished without additional time and resources, as for instance required in solutions based on solder processes. Moreover, due to the integration of the contact structure into the PCB the routing and thus layout for connecting to the remaining electronic environment may be optimized in view of specific aspects, such as operating frequency, and the like. For example, components external to the packaged semiconductor device may be placed with reduced distance with respect to the DUT, thereby reducing the length of conductors, which in turn enables high operating frequencies without causing undue voltage spikes.

In a further illustrative embodiment the support structure comprises a load mechanism configured to temporarily bias the packaged semiconductor device against the contact structure. Hence, as already discussed above, a reliable contact may be established on the basis of a normal force acting on the DUT, thereby efficiently reducing any undue locally concentrated forces at individual contact elements of the DUT, which may conventionally result in undue damage.

In a further illustrative embodiment the support structure comprises at least one guide element configured to adjust a lateral position of the packaged semiconductor device. In this manner, an exact lateral positioning of the DUT is guaranteed while at the same time allowing a rapid attachment and de-attachment of the DUT in the printed circuit board.

In one preferred embodiment the contact structure comprises conductors extending through the printed circuit board from the first surface to the second surface. In this manner, the routing capabilities in the PCB may efficiently be exploited, since at least the first and the second surface of the PCB are available for connecting to the contact elements of the DUT.

In a further illustrative embodiment the contact structure comprises elastic conductive portions. Hence, a desired degree of compliance of the contact structure may be achieved on the basis of the elastic conductive portions, thereby allowing the compensation for any non-uniformities of the height of the complementary contact structure of the DUT. In particular, by providing the conductors so as to fully extend through the PCB, as discussed in the aforementioned embodiment, a corresponding maximum length of the contact structure is available on the PCB in order to implement the desired degree of compliance without unduly contributing to the complexity of individual contact elements of the contact structure. For example, a plurality of conductive elastic materials is available, which may efficiently be used as a portion of the contact element of the contact structure.

For example, the conductors extending at least from the first surface to the second surface are formed of an elastic material, thereby providing for a high compensation capability with respect to any height non-uniformities of the complementary contact structure of the DUT.

In one illustrative embodiment, the contact structure comprises fixed or permanently attached contact elements formed on the second surface of the printed circuit board. In this manner it is ensured that a reliable and permanent mechanical attachment to the PCB is provided, irrespective of any possible elastic characteristics of other portions of the contact structure of the PCB. For example, in one illustrative embodiment the fixed or permanently attached contact elements comprise a solder material. In this manner, a very reliable electrical and mechanical contact is established to other conductive lines in the PCB, while still the remaining portions of the contact elements may provide for a reliable contact to the DUT while avoiding time-consuming solder processes.

According to a further aspect, an adapter for an electronic test system comprises a body configured to receive and laterally hold in position a packaged semiconductor device to be tested. Moreover, the adapter comprises a bottom contact structure comprising contact elements with solder material enabling connection to a printed circuit board. Furthermore, the adapter comprises a top contact structure configured to detachably connect to a complementary contact structure of the semiconductor device to be tested. Additionally, the adapter comprises an intermediate contact structure connecting the bottom contact structure to the top contact structure.

The inventive adapter thus comprises at least the bottom contact structure that is prepared so as to allow a reliable and permanent connection to a PCB or any other component of an electronic test environment due to the presence of the solder material. On the other hand, the top contact structure enables a fast and reliable installation of the DUT in the adapter. The electrical connection between the top contact structure and the bottom contact structure, which may permanently be connected to the PCB, is provided by the intermediate contact structure, which may be provided in the form of through-holes, thereby enabling the application of efficient manufacturing techniques for forming the adapter.

In one advantageous embodiment the body is formed of a silicon containing material. Hence, well-established manufacturing techniques as used for forming semiconductor-based devices may efficiently be applied in order to form the body of the adapter and thus providing an appropriate infra-structure for fabricating the top contact structure, the intermediate contact structure and the bottom contact structure. In one illustrative embodiment, the body may be comprised of silicon material, which thus allows the application of appropriate silicon manufacturing techniques. Consequently, the adapter may be formed on the basis of volume production techniques, thereby significantly reducing overall costs, while still ensuring high precision, for instance in implementing any mechanism for determining the lateral position of the DUT. That is, since well-established semiconductor production techniques, such as lithography, etch techniques, and the like may be applied on the basis of a well established base material generally any components of the adapter may be formed on the basis of dimensions that are in compliance with the semiconductor fabrication technology under consideration. In particular upon using well-established semiconductor materials, such as silicon, and the like, the body of the adapter may be formed with appropriate overall dimensions so as to avoid, on the one hand, undue material consumption, while nevertheless ensuring, on the other hand, sufficient mechanical integrity, for instance with respect to providing any guiding elements, and the like, so as to appropriately receive and hold in position the DUT. On the other hand, any conductive portions, such as the intermediate contact structure, may be formed on the basis of well-established techniques, such as forming through-holes in the silicon containing material and filling the through-holes by well-established materials, such as metals, highly doped semiconductor materials, or any combination thereof. On the other hand, reliable insulation of the conductive portions of the various contact structures may also be implemented on the basis of well-established semiconductor production techniques. For example, any other related materials, such as silicon dioxide, silicon nitride, and the like may readily be formed on the basis of the silicon containing base material by using any well-established process techniques, thereby providing for a high degree of flexibility in forming conductive structures and reliable insulation areas.

In one illustrative embodiment the top contact structure comprises planar contact areas for connecting to the complementary contact structure. In this case, the complementary contact structure of the DUT may comprise any protruding contact elements, such as solder balls, metal pillars, and the like, which may appropriately be distributed across a bottom surface of the DUT. In this case, the substantially planar contact areas of the top contact structure may provide appropriate landing areas for receiving the protruding contact elements on the basis of a mechanical force exerted in a normal direction, thereby minimizing any damage that could be induced in the protruding contact elements of the DUT. Hence, in particular highly complex contact structures of the DUTs may efficiently be received within the adapter, while the contact regime of the adapter may be provided on the basis of significantly lower manufacturing costs compared to sophisticated burn in sockets, as discussed above.

In a further illustrative embodiment the top contact structure comprises contact balls for connecting to the complementary contact structure. In this case, the top contact structure is appropriately equipped in order to receive substantially planar contact areas of the DUT, which may thus be provided in the form of a land grid array (LGA).

In a further illustrative embodiment at least one of the top contact structure and the intermediate contact structure has elastic properties so as to compensate for a pre-defined degree of height non-uniformity of the complementary contact structure. That is, a certain degree of compliance is imparted to the adapter so as to compensate for a certain degree of non-uniformities, thereby increasing the overall contact reliability during the test procedure. For example, the material used for the intermediate contact structure may provide for a certain degree of compliance so that also the contact areas of the top contact structure may allow a certain variation in height when subjected to pressure upon inserting the DUT into the adapter. It should be appreciated that generally highly precise manufacturing techniques may allow the reduction of the tolerances within the adapter, thereby also reducing the requirements with respect to compensation of any non-uniformities. That is, generally the compliance of the top contact structure and/or the intermediate contact structure may be selected so as to account for height non-uniformities of the DUT and any imperfections caused by the insulation of the DUT, while manufacturing tolerances of the adapter itself may be reduced due to the high precision process techniques used.

Generally, it is to be appreciated that the adapter may also be made from other materials, such as polymer materials, and the like, thereby also allowing the application of highly precise manufacturing techniques, wherein the respective contact structures may be formed on the basis of electroplating, inkjet printing by using appropriate materials, and the like so that the lateral dimensions of conductive areas and insulating areas may also be defined with high precision.

It should further be appreciated that the inventive adapter may be used in combination with an appropriate support structure or a load mechanism, which may allow a desired mechanical biasing of the DUT in the adapter so as to establish an electrical contact with the top contact structure without unduly damaging any contact elements of the DUT. The corresponding load mechanism may be provided as a part of the adapter or may be provided on the PCB, which is to be permanently connected with the adapter on the basis of a solder process.

According to a further aspect an electronic test system comprises a printed circuit board comprising a board contact structure. Furthermore, the electronic test system comprises an adapter according to any of the embodiments as described above or as described in the context of the detailed description, wherein the adapter is attached to the board contact structure by means of the bottom contact structure. Moreover, the electronic test system comprises a load structure configured to mechanically bias the semiconductor device to be tested.

As discussed above the electronic test system implemented on the basis of the adapter enables the application of sophisticated yet cost-effective volume production techniques for providing an appropriate detachable contact regime for receiving a DUT, while still ensuring high contact reliability at a low impact on the contact structure of the DUT, even if sophisticated contact regimes are used.

Furthermore, in order to enhance the overall heat transfer capabilities from and to the DUT heating elements and/or heat dissipating elements, such as a blower fan, Peltier elements, and the like may be provided in close proximity to the DUT in any of the inventive electronic test systems disclosed therein. In this manner, sophisticated environmental conditions may be established during the test procedure.

### BRIEF DESCRIPTION OF THE DRAWINGS

FIG. 1a schematically illustrates an electronic test system with a PCP having incorporated therein an appropriate support mechanism and a contact structure for receiving a DUT according to illustrative embodiments;

FIG. 1b schematically illustrates the electronic test system with the DUT connected thereto according to illustrative embodiments;

FIG. 2a schematically illustrates an electronic test system established on the basis of an adapter, for instance formed on the basis of a semiconductor material, according to illustrative embodiments

FIG. 2b schematically illustrates a perspective view of the electronic test system and the adapter; and

FIG. 2c schematically illustrates the electronic test system based on the inventive adapter, wherein the DUT is biased in the adapter on the basis of an appropriate load mechanism according to illustrative embodiments.

### DETAILED DESCRIPTION OF THE DRAWINGS

With reference to the accompanying drawings further illustrative embodiments will now be described in more detail.

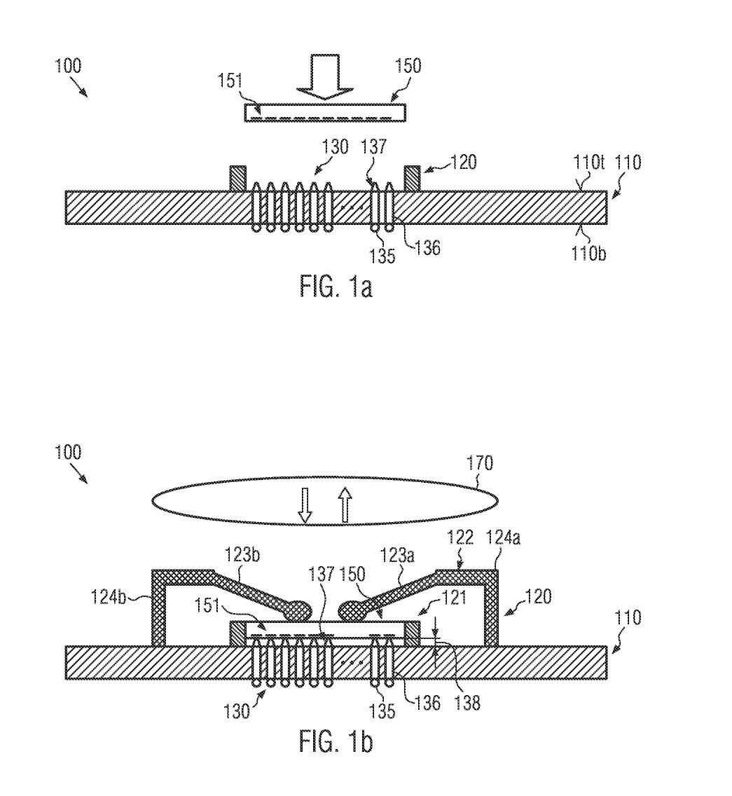

FIG. 1a schematically illustrates a cross-sectional view of an electronic test system 100, which comprises a printed circuit board (PCB) 110, which typically comprises electronic components, such as ICs (integrated circuits), discrete electronic components, such as capacitors, inductors, and the like, which are appropriately electrically connected with each other by means of a routing or wiring system (not shown), which is usually formed on one or more wiring levels of the PCP 110. For example, the PCB 110 comprises a first surface 110t, which may be the surface on which a DUT 150 is to be received and which may comprise a plurality of conductive lines (not shown) and other electronic components, as discussed above. Furthermore, the PCB 110 comprises at least a second surface 110b, which is also to be understood as a second layer of the PCP 110, in which a routing of conductive lines may be implemented. The electronic system 100 further comprises a support structure 120, which is appropriately configured so as to receive a DUT 150 and appropriately hold in position the DUT 150 during a test procedure. To this end, the support structure 120 may comprise any appropriate mechanical components, such as guide elements, and the like, in order to define an appropriate cavity above the PCB 110 so as to precisely define the lateral position of the DUT 150. Furthermore, the support structure 120 may comprise an appropriate construction for mechanically biasing the DUT 150, as will be described in more detail with reference to FIG. 1b.

Furthermore, the PCB 110 comprises a contact structure 130 that is appropriately positioned and configured so as to allow electrical contact to a complementary contact structure 151 provided in the DUT 150. In the embodiment shown, the contact structure 130 comprises contact elements 137, which are designed so as to electrically connect to the individual contact elements of the complementary contact structure 151. That is, the elements 137 have an appropriate configuration so as to connect to the respective components of the complementary contact structure 151 in order to obtain a reliable electrical contact without unduly modifying the contact structure 151, for instance by exerting undue locally concentrated mechanical forces, and the like. Furthermore, in the embodiment shown, the contact structure 130 comprises conductors 136, which extend through the PCB 110 from the first surface 110t to the second surface 110b, thereby connecting to further contact portions or elements 135, which are provided, in some illustrative embodiments, as contacts resulting in a reliable permanent connection to the surface 110b of the PCB 110. For example, the contact elements 135 are realized as elements comprising a solder material that forms an inter-metallic connection with a corresponding contact area provided on the second surface 110b. Hence, a stable and reliable mechanical attachment of the contact structure 130 to the PCB 110 is achieved by the contact elements 135, which may also be used for connecting at least some of the contact elements in the complementary contact structure 151 with electronic components provided on the PCB 110. In this manner, at least the first surface 110t and the second surface 110b may be used for the routing of the DUT in the PCB 110. It should be appreciated that further wiring layers may be implemented in the PCB 110 (not shown), depending on the overall complexity and requirements of the electronic system 100 and the DUT 150.

The conductors 136 are provided on the basis of any appropriate material that ensures the required current drive capabilities in order to comply with the maximum current requirements of the DUT. Typically, the drive current capability of the conductors 136 may be one to several amperes, thereby meeting the drive current capabilities of many sophisticated semiconductor devices. Furthermore, by providing corresponding through-holes in the PCB 110 the intermediate conductors 136 may be formed on the basis of highly efficient and well established manufacturing techniques applied in available PCB technologies, thereby allowing a minimum pitch of 0.5 mm and less according to currently practiced techniques.

FIG. 1b schematically illustrates the electronic system 100, wherein the DUT 150 is detachably connected to the PCB 110. To this end, the DUT 150 may efficiently be inserted into the cavity defined by the support structure 120, for instance based on a corresponding mechanism 121 that precisely defines the lateral position of the DUT 150. Furthermore, in this embodiment, the support structure 120 comprises a load mechanism 122, for instance formed on the basis of movable load arms 123A, 123B which may thus mechanically bias the DUT 150 against the contact structure 130, i.e. the contact elements or portions 137. The load mechanism 122 may further comprise respective stationery support components 124A, 124B which are attached to the PCB 110.

Consequently, based on the load mechanism 122 the DUT 150, held in position in the lateral directions on the basis of the mechanism 121, is brought into contact with the elements 137, wherein a well controlled mechanical force is applied normal with respect to the PCB 110 and the DUT 150, thereby avoiding undue local concentration of mechanical forces in the individual contact elements of the complementary contact structure 151. On the other hand, a reliable electrical contact is established for each of a plurality of DUTs processed in the electronic test system 100, thereby ensuring highly uniform test conditions for a large number of devices to be tested. Also the advantages with respect to superior routing conditions in the PCB as well as the application of well-established test programs may be achieved by using the electronic test system 100.

Moreover, as discussed above, superior heat transfer capabilities may be implemented in the system 100 by providing appropriate components, generally indicated as 170. For example, thermally active components, such as Peltier elements, heating elements, components for carrying a heat transfer fluid, and the like may be positioned so as to be in close proximity to the DUT 150 or may be in direct contact with specific surface areas of the DUT 150. In other cases, heat dissipation capabilities may be enhanced by providing a fan at or near the DUT 150. Consequently, sophisticated test conditions may be established in the electronic test system 100 as required for specified test cycles, such as burn in procedures, and the like.

Furthermore, in some illustrative embodiments, the contact structure 130 is configured such that a certain degree of compliance or elasticity is achieved, thereby allowing the compensation of a certain degree of height non-uniformities that may be present in the contact structure 130 and/or in the contact structure 151. To this end, one or more components, such as the components 137 and 136 may be implemented on the basis of a corresponding mechanical configuration and/or on the basis of appropriate material characteristics. For example, height differences, as indicated by 138, may be compensated individually for each contact element on the basis of the compliance or electricity provided in the contact structure 130, thereby ensuring a reliable electrical contact even for highly complex contact regimes of the DUT 150. For example, a resilient or elastic material may be used when filling the through-holes in the PCB 110 so as to exploit the elastic characteristics of the conductive material used. To this end, a plurality of conductive materials having elastic characteristics is available in the art and may be used for forming the contact structure 130. In other cases, pre-manufactured contact elements providing for elasticity at desired high conductivity may be implemented in the PCB 110 so as to form the contact structure 130.

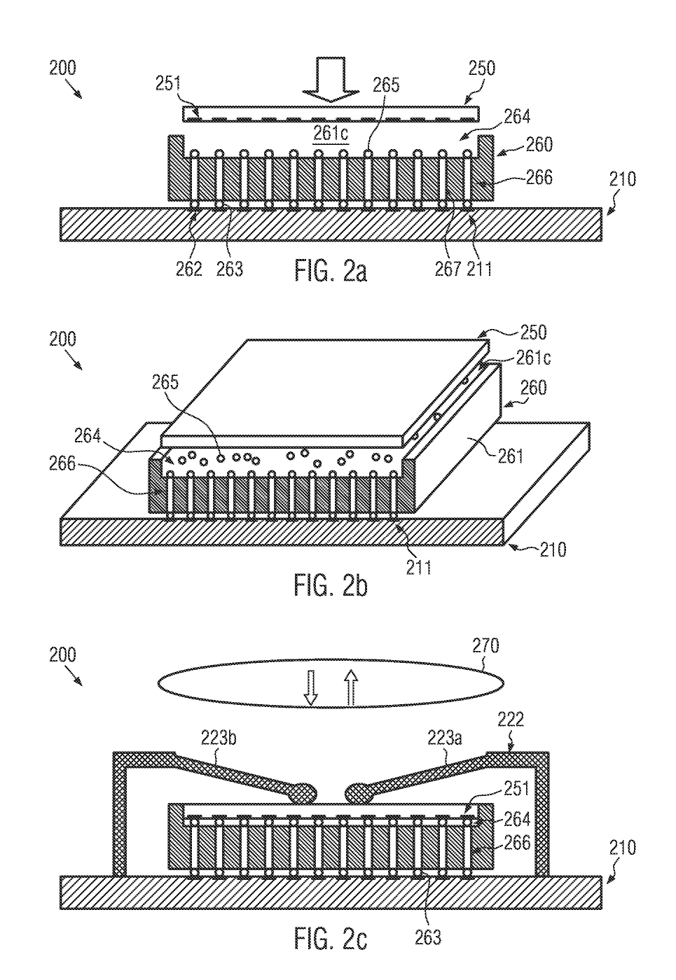

FIG. 2a schematically illustrates a cross-sectional view of an electronic test system 200, in which an adapter 260 is used for connecting to a PCB 210. The adapter 260 comprises a body 261 formed of any appropriate material, wherein in some illustrative embodiments a silicon containing material or any other material is used, which allows the application of semiconductor-based manufacturing techniques. For example, the body 261 is formed of silicon material, thereby enabling the application of well-established semiconductor fabrication techniques. The body 261 is formed so as to define a cavity 261c, which thus allows a device to be tested (DUT) 250 to be inserted and thus precisely define the lateral position of the DUT 250. For example, when forming the body 261 on the basis of semiconductor fabrication technologies, the cavity 261c may be formed with tolerances of the lateral dimensions that comply with alignment and patterning tolerances of sophisticated semiconductor production techniques. Furthermore, the adapter 260 comprises a top contact structure 264 formed within the cavity 261c and appropriately configured so as to reliably connect to a complementary contact structure 251 formed at a bottom surface of the DUT 250. Thus, the layout of the top contact structure 264 corresponds to the layout of the contact structure 251, while additionally respective contact areas or elements 265 of the structure 264 are appropriately configured so as to establish a reliable electrical contact without unduly mechanically affecting the respective contact elements or areas of the complementary contact structure 251. For example, the contact elements 265 may be provided in the form of protruding contact elements, such as balls, metal pillars and the like, wherein the contact structure 251 is implemented in the form of a land grid array, while in other cases, contact pads may be provided as the contact elements 265, if a corresponding ball grid array is implemented in the complementary contact structure 251. The contact elements 265 are formed on the basis of any appropriate material or material composition, for instance using gold, and the like, in order to achieve similar contact characteristics for a large number of DUTs to be processed in the system 200.

The adapter 260 further comprises a bottom contact structure 262, which may comprise appropriate contact portions or elements 263 that are configured to be permanently connected to a corresponding contact structure 211 provided on the PCB 210. In some illustrative embodiments, the contact elements 263 comprise a solder material which allows an efficient electrical and mechanical connection of the adapter 260 to the PCB 210, irrespective of the complexity of the layout of the contact structures. Furthermore, an intermediate contact structure 266 of the adapter 260 provides for electrical communication between the bottom contact structure 262 and the top contact structure 264. In some illustrative embodiments, the intermediate contact structure 266 comprising respective conductors 267 is implemented in the form of through-hole vias, which may be formed in the body 261 by any appropriate manufacturing technique. As discussed above, when providing the body 261 in the form of a material as used for microelectronic or micro mechanical devices, corresponding highly efficient etch techniques may be used in combination with respective deposition processes in order to refill the through-holes with an appropriate conductive material. For example, for silicon-based materials well established etch strategies are available in order to form through-holes with precisely defined cross-sectional shapes and lateral pitch, thereby accommodating the requirements of currently available and future highly sophisticated contact regimes. In other cases, the intermediate contact structure 260, possibly in combination with the contact structure 264 may be formed on the basis of other well-established techniques including electroplating, inkjet printing in combination with appropriate dielectric materials, such as polymer materials, and the like. It should be appreciated that corresponding processes and materials are also well-established in sophisticated packaging technologies and hence also in this case high precision and reduced cost may be achieved by using any such volume production techniques.

FIG. 2b schematically illustrates a perspective view of the electronic test system 200, wherein the adapter 260 is already permanently attached to the PCB 210. As shown, the contact structures of the adapter 260, i.e. the top contact structure 264, the intermediate contact structure 266 and the bottom contact structure 263 have any appropriate layout so as to comply with the requirements of the DUT 250. On the other hand, irrespective of the complexity of the contact regime of the DUT 250 the associated layout of the contact structures of the adapter 260 may be provided with high precision and low-cost, while also reduced lateral dimensions may be implemented by applying the above identified sophisticated volume production techniques. That is, when using, for instance, a silicon-based material for the adapter 260 the cavity 261c may be provided with high precision and a high degree of reproducibility so that the cavity 261c may have reduced lateral dimensions that are comparable to the dimensions of the DUT 250 while still ensuring a precise lateral positioning of the DUT 250 due to the precise form closure between the cavity 261c and the DUT 250. Similarly, the various contact structures of the adapter 260 may be formed with high precision without requiring additional space within the body 261 for appropriately connecting the contact structure 264 to the contact structure 211 of the PCB 210, since the contact elements in the adapter 260 may be established on the basis of techniques, which provide for superior alignment and routing accuracy compared to any available or future printed circuit board technology. That is, irrespective of the capabilities of the printed circuit board technology and irrespective of the complexity of the contact regime of the DUT 250 the routing within the body 261 may be realized on the basis of layout constraints imparted by the contact structure 211 of the PCB 210, which may readily be met by the techniques used for forming the contact structures in the adapter 260, since the involved volume production techniques allow significantly smaller lateral dimensions and pitches compared to the contact structure 211.

FIG. 2c schematically illustrates the electronic test system 200 in a situation, in which the DUT 250 is received by the adapter 260 and is mechanically biased on the basis of a load mechanism 222, which comprises stationery components rigidly attached to the PCB 210 and movable components 223A, 223B. Hence, also in this case, mechanical force or pressure may be applied to the DUT 250 so as to establish a reliable electrical contact between the structure 251 and the top contact structure 264 without unduly modifying or damaging the contact structure 251. On the other hand, the material characteristics of the contact structure 264 may ensure a reliable electrical contact with very similar resistance even after inserting and removing a plurality of DUTs into and from the adapter 260. Moreover, as discussed above, the intermediate contact structure 266 and/or the top contact structure 264 may provide for a certain degree of compliance or elasticity so as to compensate for a certain degree of height non-uniformity of the contact structure 251, while, as discussed above, the tolerances with respect to any imperfections or non-uniformities of the body 261 and the contact structure 264 may be significantly reduced due to the application of well established and highly precise volume production techniques.

Furthermore, in order to enhance heat transfer capabilities in the system 200 respective components 270, such as heaters, cooling devices, and the like may be provided so as to be positionable in close proximity to the DUT 250 or any other components placed on the PCB 210 in order to implement any required sophisticated test conditions.

As a result, the present invention provides electronic systems and adapters to be used in electronic test system, wherein DUTs may be installed and of the test environment in a fast and efficient manner without unduly modifying the contact structure of the DUTs, while nevertheless a high degree of reliability of the elected the contact is achieved for a large number of DUTs. On the other hand, the reliable contact of the DUTs with the PCB of the test environment may be realised by an appropriate configuration of the PCB itself or by using a corresponding adapter, wherein in both cases sophisticated volume production techniques ensure high precision and low overall cost. Moreover, increased the ability in optimizing the routing on the PCB may be achieved while also allowing the application of well-established test programs as are also implemented during electrical test procedures when fabricating the DUTs.

What is claimed is:

1. An electronic test system, comprising
a printed circuit board having a first surface and an oppositely arranged second surface;
a support structure attached to said printed circuit board and configured to receive and hold in position a packaged semiconductor device to be tested; and
a contact structure formed on said printed circuit board and configured to directly and removably connect to a complementary contact structure of said packaged semiconductor device to be tested.

2. The electronic test system of claim 1, wherein said support structure comprises a load mechanism configured to temporarily bias said packaged semiconductor device against said contact structure.

3. The electronic test system of claim 1, wherein said support structure comprises at least one guide element configured to fix a lateral position of said packaged semiconductor device.

4. The electronic test system of claim 1, wherein said contact structure comprises conductors extending through said printed circuit board from said first surface to said second surface.

5. The electronic test system of claim 1, wherein said contact structure comprises elastic conductive portions.

6. The electronic test system of claim 4, wherein said conductors are formed of an elastic material.

7. The electronic test system of claim 4, wherein said contact structure comprises fixed contact elements formed on said second surface of said printed circuit board.

8. The electronic test system of claim 7, wherein said fixed contact elements comprise a solder material.

9. An adapter for an electronic test system, comprising:
a body configured to receive and laterally hold in position a packaged semiconductor device to be tested;
a bottom contact structure comprising contact elements with solder material so as to connect to a printed circuit board;
a top contact structure configured to detachably connect to a complementary contact structure of said semiconductor device to be tested and
an intermediate contact structure connecting said bottom contact structure to said top contact structure.

10. The adapter for an electronic test system of claim 9, wherein said body is formed of a silicon containing material.

11. The adapter for an electronic test system of claim 10, wherein said intermediate contact structure comprises through-hole vias formed in said silicon containing material.

12. The adapter for an electronic test system of claim 9, wherein said top contact structure comprises planar contact areas for connecting to said complementary contact structure.

13. The adapter for an electronic test system of any claim 9, wherein said top contact structure comprises contact balls for connecting to said complementary contact structure.

14. The adapter for an electronic test system of claim 9, wherein at least one of said top contact structure and said intermediate contact structure has elastic properties so as to compensate for a pre-defined degree of height non-uniformity of said complementary contact structure.

15. The adapter for an electronic test system of claim 9, further comprising a load mechanism configured to temporarily bias said packaged semiconductor device against said top contact structure.

16. An electronic test system, comprising
a printed circuit board comprising a board contact structure;
an adapter comprising:
a body configured to receive and laterally hold in position a packaged semiconductor device to be tested;
a bottom contact structure comprising contact elements with solder material so as to connect to a printed circuit board;
a top contact structure configured to detachably connect to a complementary contact structure of said semiconductor device to be tested and
an intermediate contact structure connecting said bottom contact structure to said top contact structure;
said adapter being attached to said board contact structure through said bottom contact structure; and
a load structure configured to mechanically bias said semiconductor device to be tested against said top contact structure.
